(19) United States
(12) Patent Application Publication
(10) Pub. No.: US 2025/0062730 A1
(43) Pub. Date: Feb. 20, 2025

(54) LINEARIZATION USING FETS WITH DESIGNABLE PINCH OFF VOLTAGE

(71) Applicant: SKYWORKS SOLUTIONS, INC., Irvine, CA (US)

(72) Inventors: Yu Zhu, Wellesley, MA (US); Binghui Li, Winchester, MA (US); Oleksiy Klimashov, Burlington, MA (US); Dylan Charles Bartle, Arlington, MA (US); Paul T. DiCarlo, Marlborough, MA (US)

(21) Appl. No.: 18/792,788

(22) Filed: Aug. 2, 2024

Related U.S. Application Data
(60) Provisional application No. 63/532,765, filed on Aug. 15, 2023.

(51) Int. Cl. H03F 3/24; H03F 1/02

(52) U.S. Cl. CPC H03F 3/245; H03F 1/0211; H03F 2200/18

(57) ABSTRACT

Examples of the disclosure include a power amplifier comprising an input to receive an input signal, an output to provide an amplified output signal, a gate voltage bias node to receive a gate voltage bias signal, a first amplifier device having a first gate connection coupled to the gate voltage bias node and configured to receive the gate voltage bias signal, and a second amplifier device having a second gate connection coupled to the gate voltage bias node and configured to receive the gate voltage bias signal.

### CROSS-REFERENCE TO RELATED APPLICATIONS

This application claims priority under 35 U.S.C. § 119 (e) to U.S. Provisional Application Ser. No. 63/532,765, titled “LINEARIZATION USING FETS WITH DESIGNABLE PINCH OFF VOLTAGE,” filed on Aug. 15, 2023, which is hereby incorporated by reference in its entirety.

### BACKGROUND

### 1. Field of the Disclosure

At least one example in accordance with the present disclosure relates generally to power amplifiers.

### 2. Discussion of Related Art

Power amplifiers amplify power signals. A power amplifier receives an input signal, amplifies the input signal to produce an amplified output signal, and provides the amplified output signal to an output. A power amplifier may amplify the input signal according to a gain value, which specifies an amount by which the input signal is to be amplified.

### SUMMARY

According to at least one aspect of the present disclosure, a power amplifier is provided comprising an input to receive an input signal, an output to provide an amplified output signal, a gate voltage bias node to receive a gate voltage bias signal, a first amplifier device having a first gate connection coupled to the gate voltage bias node and configured to receive the gate voltage bias signal, and a second amplifier device having a second gate connection coupled to the gate voltage bias node and configured to receive the gate voltage bias signal.

In at least one example, the power amplifier a drain voltage bias node to receive a drain voltage bias signal, wherein the first amplifier device includes a first drain connection coupled to the drain voltage bias node and configured to receive the drain voltage bias signal and the second amplifier device includes a second drain connection coupled to the drain voltage bias node and configured to receive the drain voltage bias signal. In at least one example, the first amplifier device includes a first source connection coupled to a reference node and the second amplifier device includes a second source connection coupled to the reference node. In at least one example, the power amplifier includes a third amplifier device having a third gate connection coupled to the gate voltage bias node and configured to receive the gate voltage bias signal, a third drain connection coupled to the drain voltage bias node and configured to receive the drain voltage bias signal, and a third source connection coupled to the reference node.

In at least one example, the power amplifier includes a third amplifier device having a third gate connection coupled to the gate voltage bias node and configured to receive the gate voltage bias signal and a third drain connection coupled to the drain voltage bias node and configured to receive the drain voltage bias signal. In at least one example, the power amplifier includes a third amplifier device having a third gate connection coupled to the gate voltage bias node and configured to receive the gate voltage bias signal. In at least one example, the first amplifier device is a primary amplifying device and the second amplifier device is an auxiliary biasing device. In at least one example, the power amplifier includes at least one additional auxiliary biasing device.

In at least one example, at least one operating parameter of the auxiliary biasing device and the at least one additional auxiliary biasing device is selected to yield a respective desired value of at least one performance parameter under at least one operating condition. In at least one example, the at least one operating parameter includes at least one of a pinch-off voltage and a gate width. In at least one example, the at least one performance parameter includes at least one of third-order transconductance, third-order intermodulation, input third-order intercept point, or output third-order intercept point. In at least one example, the at least one operating condition includes a value of the gate voltage bias signal.

In at least one example, at least one operating parameter of the auxiliary biasing device is selected to yield a respective desired value of at least one performance parameter under at least one operating condition. In at least one example, the at least one operating parameter includes at least one of a pinch-off voltage and a gate width. In at least one example, the at least one performance parameter includes at least one of third-order transconductance, third-order intermodulation, input third-order intercept point, or output third-order intercept point. In at least one example, the at least one operating condition includes a value of the gate voltage bias signal.

According to at least one aspect of the disclosure, a method of operating a power amplifier including an input, an output, a gate voltage bias node, a first amplifier device, and a second amplifier device is provided, the method comprising receiving an input signal at the input, amplifying, by at least one of the first amplifier device or the second amplifier device, the input signal to produce an amplified output signal, providing the amplified output signal to the output, and providing a gate voltage bias signal to a first gate connection of the first amplifier device and to a second gate connection of the second amplifier device.

In at least one example, the method includes providing a drain voltage bias signal to a first drain connection of the first amplifier device and to a second drain connection of the second amplifier device. In at least one example, the method includes selecting a value of at least one operating parameter of the second amplifier device based on the gate voltage bias signal. In at least one example, the at least one operating parameter includes at least one of a pinch-off voltage and a gate width.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a wireless device according to an example;

FIG. 2 illustrates a schematic diagram of a power amplifier according to an example;

FIG. 3 illustrates a schematic diagram of a power amplifier according to an example;

FIG. 4 illustrates a graph showing gm3 values as a function of gate voltage for devices having various pinch-off voltages according to an example;

FIG. 5 illustrates a graph depicting how derivative superposition may be applied to yield desired operating conditions according to an example;

FIG. 6 illustrates a graph of a net gm3 value as a function of gate voltage according to an example;

FIG. 7 illustrates a graph depicting an IM3 value as a function of gate voltage according to an example;

FIG. 8 illustrates a graph depicting an IM3 value as a function of gate voltage according to another example;

FIG. 9 illustrates a schematic diagram of a power amplifier according to another example; and

FIG. 10 illustrates a process of implementing a power amplifier according to an example.

### DETAILED DESCRIPTION

As discussed above, power amplifiers may be used to amplify input signals pursuant to a gain value. An ideal power amplifier may exhibit a perfectly linear gain, that is, an amplifier with a constant gain independent of the magnitude of the input signal. In a nonlinear device, the output signal may be distorted relative to the input signal. One measure of this nonlinear distortion includes third-order transconductance (gm3). It may be advantageous to minimize the gm3 value to improve linearity of the power amplifier. While other performance parameters may also be considered in evaluating a nonlinear device, gm3 is used as an example for purposes of the following discussion.

The gm3 value may be adjusted by varying certain parameters of the power amplifier. One example of a power amplifier, discussed in greater detail below, implements a pair of parallel-connected field-effect transistors (FETs). The FETs may be fabricated to be substantially identical. However, each FET may receive a different gate bias voltage to yield desired power-amplification characteristics (for example, by minimizing a gm3 value) from the power amplifier. Implementing multiple gate bias voltages may consume valuable die area and increase design complexity.

Examples of the disclosure provide power amplifiers implementing amplifying devices (for example, FETs) configured to be biased by the same gate-bias-voltage source. In some examples, two or more FETs may be coupled in parallel. Each FET may be designed to have a particular gate width and pinch-off voltage. Modulating the gate widths and pinch-off voltages of the FETs allows minimization of a gm3 value of the power amplifier at a desired gate voltage while applying the same gate bias voltage to each of the two or more FETs. In various examples, power amplifiers disclosed herein may include two parallel-connected FETs. However, some power amplifiers disclosed herein may include more than two FETs. Additional FETs may be added to, for example, increase an operating range of gate voltages over which the gm3 value is minimized. Accordingly, examples disclosed herein include power amplifiers implementing two or more FETs biased by the same gate voltage bias with a high degree of linearity.

Examples of the disclosure may be implemented in connection with power amplifiers in many types of electronic devices or systems, such as consumer electronics (for example, televisions, gaming consoles, personal computers, tablet computers, desktop computers, and so forth), vehicles, communication equipment, electrical-utility equipment, or other devices or systems having power amplifiers. For purposes of explanation, examples are provided with reference to wireless devices. For example, a wireless device may include a mobile telephone, such as a smartphone. However, the principles of the disclosure are more broadly applicable to power amplifiers in any of various devices or systems, and wireless devices are described for purposes of example only.

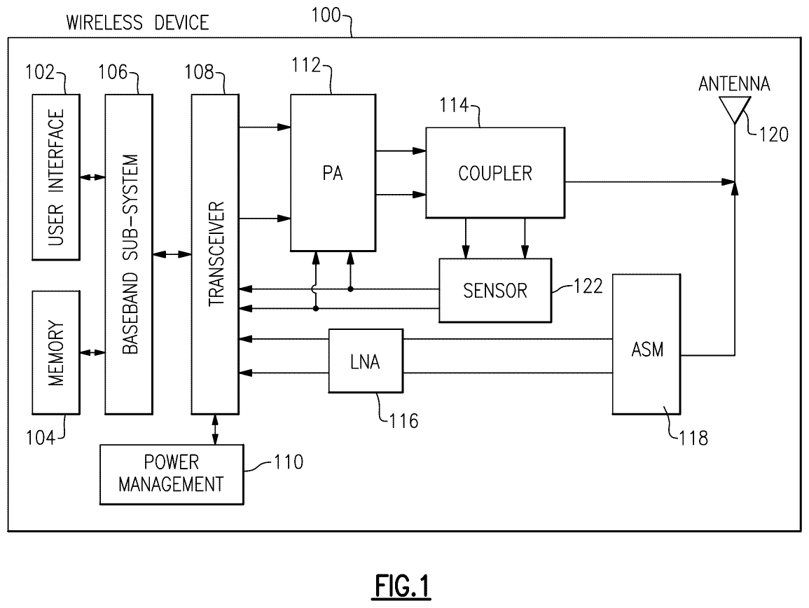

FIG. 1 illustrates a block diagram of a wireless device 100 according to an example. The wireless device 100 can be a cellular phone, smart phone, tablet, modem, communication network or any other portable or non-portable device configured for voice and/or data communication. The implementations shown in FIG. 1 is exemplary and non-limiting. The wireless device 100 includes a user interface 102, memory and/or storage 104, a baseband sub-system 106, a transceiver 108, a power-management system 110, a power-amplifier (PA) module 112, a coupler 114, a low-noise amplifier (LNA) 116, a switching circuit 118 (also referred to as an antenna switch module [ASM]), an antenna 120, and at least one sensor 122.

The antenna 120 is configured to transmit and/or receive one or more signals, such that the wireless device 100 may communicate with one or more external devices via the antenna 120. The antenna 120 may include a single antenna, or multiple antennas. The transceiver 108 is configured to generate signals for transmission and/or to process received signals. In some embodiments, transmission and reception functionalities can be implemented in separate components (for example, a transmit module and a receiving module) or be implemented in the same module.

Signals generated for transmission are provided from the transceiver 108 to the PA module 112, which amplifies the generated signals from the transceiver 108. As will be appreciated by those skilled in the art, the PA module 112 can include one or more power amplifiers. The PA module 112 can be used to amplify a wide variety of radio-frequency (RF) or other frequency-band transmission signals. For example, the PA module 112 can receive an enable signal that can be used to pulse the output of the power amplifier to aid in transmitting a wireless local-area-network (WLAN) signal or any other suitable pulsed signal. The PA module 112 can be configured to amplify any of a variety of types of signal, including, for example, 5G signals, a Global System for Mobile (GSM) signal, a code-division multiple-access (CDMA) signal, a W-CDMA signal, a Long-Term-Evolution (LTE) signal, or an EDGE signal. In certain embodiments, the PA module 112 and associated components including switches and the like can be fabricated on GaAs substrates using, for example, pHEMT or BiFET transistors, or on a silicon substrate using CMOS transistors. The wireless device 100 also includes the LNA 116, which may include one or more power amplifiers configured to amplify received signals in a similar or different manner as power amplifier(s) of the PA module 112.

The wireless device 100 also includes the switching circuit 118, which is configured to switch between different bands and/or modes. For example, the switching circuit 118 may be configured to couple the LNA 116 to the antenna 120 in a receive mode of operation and to decouple the LNA 116 from the antenna 120 in a transmit mode of operation. Similarly, the PA module 112 is coupled to the antenna 120 such that signals provided to the antenna 120 from the PA module 112 in the transmit mode of operation bypass the receive path (and switching circuit 118) of the wireless device 100.

Accordingly, in certain embodiments the antenna 120 can both receive signals that are provided to the transceiver 108 via the switching circuit 118 and the LNA 116 and also transmit signals from the wireless device 100 via the transceiver 108, the PA module 112, and the coupler 114. However, in other examples multiple antennas can be used for different modes of operation.

The power-management system 110 is connected to the transceiver 108 and is configured to manage the power for the operation of the wireless device 100. The power-management system 110 can also control the operation of the wireless device 100, such as by controlling components of power amplifier(s) of the PA module 112 and/or LNA 116. Controlling components of the PA module 112 may include, for example, selecting and/or providing bias signals to power-amplification devices (for example, FETs) within the PA module 112. The power-management system 110 can include, or can be connected to, a battery that supplies power for the various components of the wireless device 100. The power-management system 110 can further include one or more processors or controllers that can control the transmission of signals and can also configure components of the wireless device 100 based upon the frequency of the signals being transmitted or received, for example. In addition, the processor(s) or controller(s) of the power-management system 110 may provide control signals to actuate switches, tune components, or otherwise configure components of the wireless device 100, such as components of the PA module 112 and/or LNA 116, as discussed below. In at least one embodiment, the processor(s) or controller(s) of the power-management system 110 can also provide control signals to control the switching circuit 118 to operate in the transmit or receive mode.

In one embodiment, the baseband sub-system 106 is connected to the user interface 102 to facilitate various input and output of voice and/or data provided to and received from the user. The baseband sub-system 106 can also be connected to the memory and/or storage 104 which is configured to store data and/or instructions to facilitate the operation of the wireless device, and/or to provide storage of information for the user.

The wireless device 100 also includes the coupler 114 having one or more coupler sections for measuring transmitted power signals from the PA module 112 and for providing one or more coupled signals to at least one sensor 122. In various examples, the wireless device 100 includes one or more couplers in addition to, or in lieu of, the coupler 114 to measure transmitted power signals from the LNA 116.

The at least one sensor 122 can in turn send information to the transceiver 108, power-management system 110, and/or directly to the PA module 112 and/or LNA 116 as feedback for making adjustments to regulate the power level of the PA module 112 and/or LNA 116. In this way the coupler 114 can be used to boost/decrease the power of a transmission signal having a relatively low/high power. It will be appreciated, however, that the coupler 114 can be used in a variety of other implementations.

For example, in certain embodiments in which the wireless device 100 is a mobile phone having a time division multiple access (TDMA) architecture, the coupler 114 can advantageously manage the amplification of an RF transmitted power signal from the PA module 112 and/or LNA 116. In a mobile phone having a TDMA architecture, such as those found in GSM, CDMA, and W-CDMA systems, the PA module 112 can be used to shift power envelopes up and down within prescribed limits of power versus time. For instance, a particular mobile phone can be assigned a transmission time slot for a particular frequency channel. In this case the PA module 112 and/or LNA 116 can be employed to aid in regulating the power level one or more RF power signals over time, so as to prevent signal interference from transmission during an assigned receive time slot and to reduce power consumption. In such systems, the coupler 114 can be used to measure the power of a power-amplifier output signal to aid in controlling the PA module 112 and/or LNA 116, as discussed above.

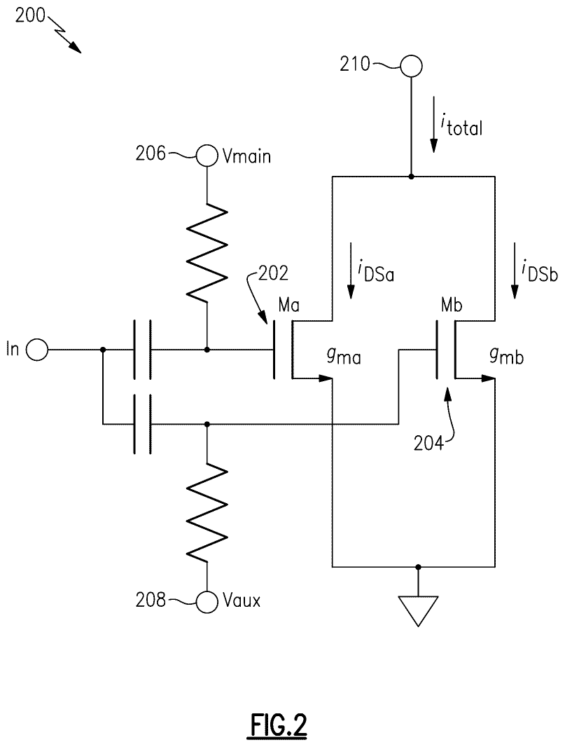

The PA module 112 may be implemented according to any of various topologies. For example, FIG. 2 illustrates a schematic diagram of a power amplifier 200 according to an example. The power amplifier 200 includes a first device 202 coupled in parallel with a second device 204. Each of the devices 202, 204 may be the same type of device (for example, a metal-oxide-semiconductor field-effect transistor [MOSFET]). However, each of the devices 202, 204 may operate differently based on received bias signals. For example, the first device 202 may be a main amplifying device operated as a depletion-mode MOSFET (DFET), and the second device 204 may be an auxiliary amplifying device operated as an enhancement-mode MOSFET (EFET).

Operation of the devices 202, 204 (including, for example, whether the devices 202, 204 are characterized as DFETs or EFETs) may depend at least in part on bias parameters applied to the devices 202, 204. Bias parameters may include, for example, a gate voltage applied to the gate of the first device 202 via a first gate bias node 206, a gate voltage applied to the gate of the second device 204 via a second gate bias node 208, a drain voltage applied to the devices 202, 204 via a drain bias node 210, and so forth. Bias signals may be applied by a component of the device 100, such as the power-management system 110, configured to output a signal of a desired voltage. Using the first device 202 as an example, modifying the drain voltage applied to the drain of the first device 202 via the drain bias node 210 may modify parameters such as the drain current (Id) and the transconductance (gm).

A derivative superposition technique may be implemented to bias the devices 202, 204. In derivative superposition, a gm3 value of each of the devices 202, 204 is added to produce a net gm3 value reflecting the gm3 value that an input signal is subjected to. Accordingly, while the first device 202 may be used as a primary amplifying device to amplify an input signal, the second device 204 may be used as an auxiliary device to bias the power amplifier 200 at desired conditions.

In various examples, the devices 202, 204 may be manufactured to be substantially identical devices. However, the devices 202, 204 may each be biased differently (for example, by biasing the gates of the devices 202, 204 with respective gate bias voltages) to produce desired bias conditions. That is, although the devices 202, 204 may be substantially identical structurally, the different bias signals provided to the devices 202, 204 cause the devices 202, 204 to behave in a desired manner.

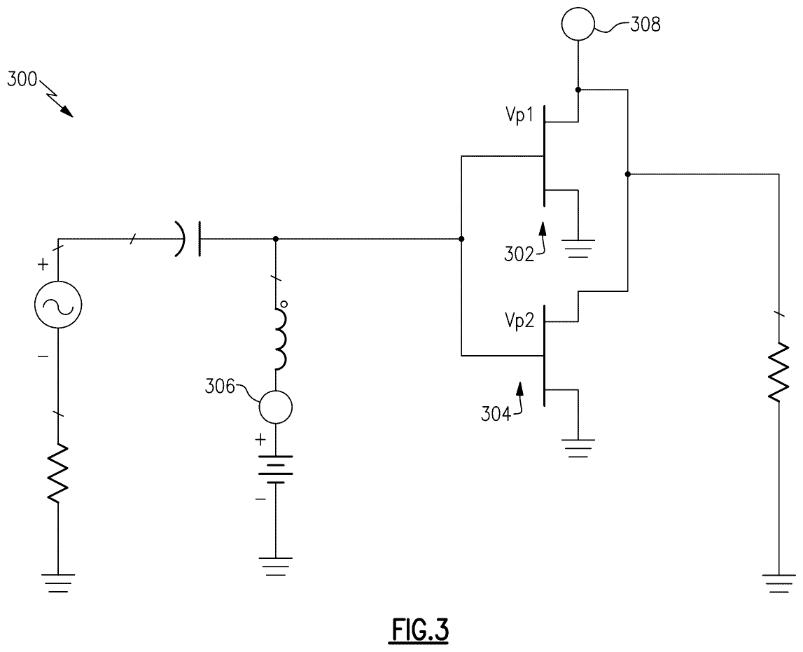

In another example, a power amplifier may be implemented at desired bias conditions pursuant to an alternate implementation. For example, FIG. 3 illustrates a schematic diagram of a power amplifier 300 according to an example. The power amplifier 300 includes a first device 302 and a second device 304. In some examples, each of the devices 302, 304 may be a switching device (for example, a MOSFET). Each of the devices 302, 304 receives a gate bias voltage from a gate voltage node 306, and receives a drain bias voltage from a drain voltage node 308. Each of the devices 302, 304 is coupled to the gate voltage node 306 at a respective gate connection, is coupled to the drain voltage node 308 at a respective drain connections, and is coupled to a reference node (for example, a ground node) at a respective source connection.

As discussed above, the devices 202, 204 may be substantially identical devices that are biased under different conditions to arrive at desired bias conditions for the power amplifier 200. Conversely, the devices 302, 304 may receive substantially identical bias signals from the nodes 306, 308, but may be designed with different structures to arrive at desired bias conditions for the power amplifier 300. For example, where the first device 302 is a primary amplifying device and the second device 304 is an auxiliary biasing device, the second device 304 may be designed with a configurable pinch-off voltage and/or gate width to arrive at a desired bias condition for the power amplifier 300. That is, the pinch-off voltage and/or gate width of a biasing device may be controlled to arrive at desired bias conditions for a power amplifier.

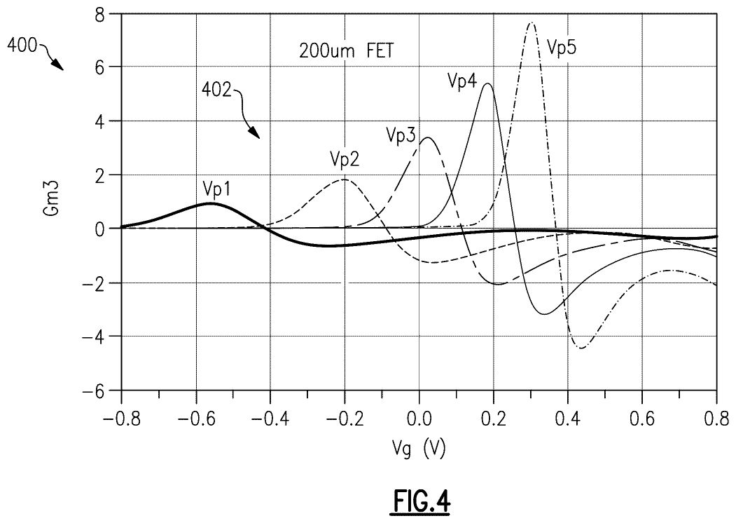

FIG. 4 illustrates a graph 400 showing gm3 values as a function of gate voltage for devices having various pinch-off voltages according to an example. The graph 400 includes various traces 402, each corresponding to a gm3 value as a function of gate voltage for a device with a different respective pinch-off voltage Vp1-Vp5. The pinch-off voltage of a device may be controlled by varying the height of the Schottky diode barrier of the device. As illustrated by the traces 402, varying the pinch-off voltage of a device may yield different gm3-versus-gate-voltage traces. Accordingly, a pinch-off voltage may be selected to yield a desired gm3-versus-gate-voltage trace, and the principles of derivative superposition may be applied to yield a desired gm3 value at a given set of operating conditions (for example, at a desired gate voltage bias point).

Operating conditions may include conditions under which a power amplifier, and/or devices making up the power amplifier, operates. For example, an operating gate voltage may be set for the power amplifier pursuant to other design considerations. Conversely, operating parameters may include controllable parameters that are selected to yield optimal or desired performance under given operating conditions. An optimal value of a given operating parameter may depend on the operating conditions. For example, as discussed in greater detail below, operating conditions such as gate voltage may be determined initially, and operating parameters (for example, a pinch-off voltage, a gate width, and so forth) may then be selected to yield optimal performance at or around those operating conditions.

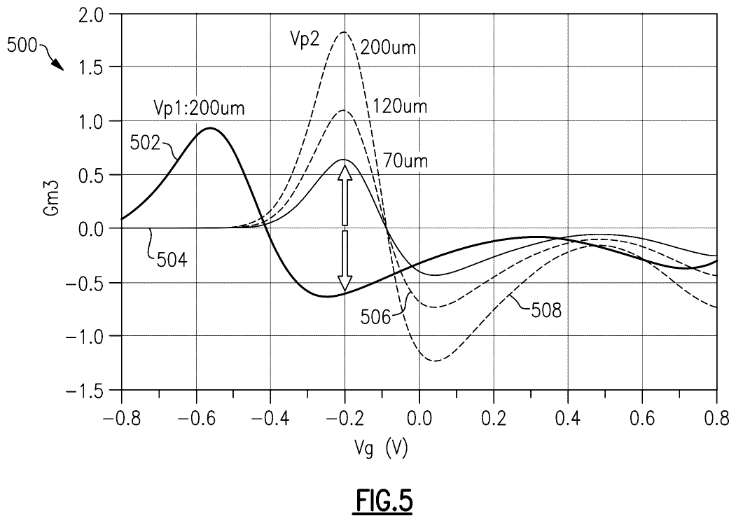

FIG. 5 illustrates a graph 500 depicting how derivative superposition may be applied to yield desired operating conditions according to an example. A first trace 502 indicates a gm3 value as a function of gate voltage for a first device. For example, the first device may be a main amplifying device, such as the first device 302. A second trace 504 indicates a gm3 value as a function of gate voltage for a second device. For example, the second device may be an auxiliary amplifying device, such as the second device 304.

In various examples, a shape of the second trace 504 may be dictated at least in part by the pinch-off voltage of the second device 304. An amplitude of the second trace 504 may be dictated at least in part by a gate width of the second device 304. For example, while the second trace 504 may correspond to a device with a gate width of approximately 70 μm and a given pinch-off voltage, a third trace 506 may correspond to an otherwise identical device (for example, having the same pinch-off voltage) with a gate width of approximately 120 μm, and a fourth trace 508 may correspond to an otherwise identical device with a gate width of approximately 200 μm. Accordingly, both a pinch-off voltage and a gate width of the second device 304 may be controlled to yield desired bias conditions for the power amplifier 300.

Which bias conditions are considered desired may depend at least in part based on performance parameters. Performance parameters include parameters quantifying the performance of a power amplifier. For example, a performance parameter of the power amplifier 300 may include the gm3 value, and the desired state of the gm3 value may be approximately zero at an operating gate voltage, that is, a gate voltage that is applied during normal operation of the power amplifier 300. Suppose, with reference to FIG. 5, that a desired operating gate voltage is approximately −0.2 V. The second device 304 may be designed with a pinch-off voltage and gate width that produce a gm3 value equal and opposite to the gm3 value of the first device 302 at an operating gate voltage. For example, if the second device 304 is designed with the parameters corresponding to the second trace 504, a net value of the first trace 502 and the second trace 504 at the operating gate voltage of −0.2 V is approximately zero. Accordingly, by designing the second device 304 with an appropriate pinch-off voltage and gate width, a net gm3 value may be approximately zero at the desired operating conditions.

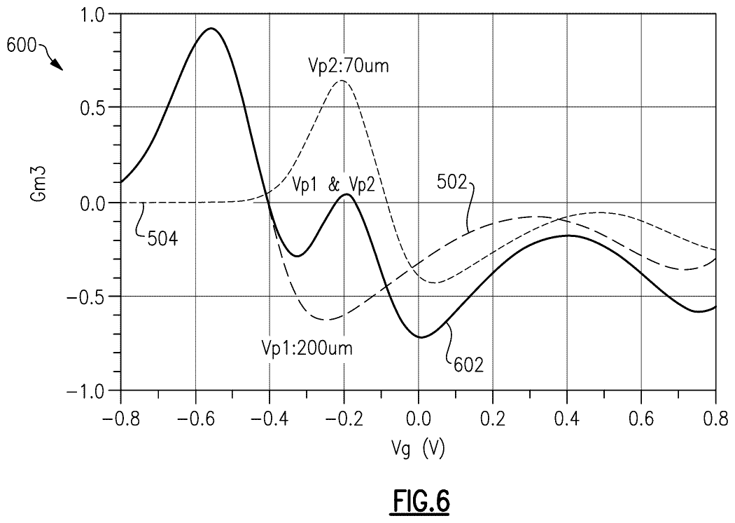

To further illustrate this principle, FIG. 6 illustrates a graph 600 of a net gm3 value as a function of gate voltage according to an example. The graph 600 includes the first trace 502 and the second trace 504 of FIG. 5, as well as a third trace 602 illustrating a net value of the traces 502, 504. The third trace 602 thus represents the gm3 value of the power amplifier 300 as a whole as a function of gate voltage. As illustrated by the third trace 602, the net gm3 value is approximately zero around a gate voltage of −0.2 V. Accordingly, when the power amplifier 300 is biased at a gate voltage of approximately −0.2 V at the gate voltage node 306, the gm3 value of the power amplifier 300 may be minimized. In other examples in which a different gate voltage bias point is desirable, a pinch-off voltage and/or gate width of the second device 304 may be manipulated to produce desired performance parameters (for example, desired gm3 performance) around the operating gate voltage.

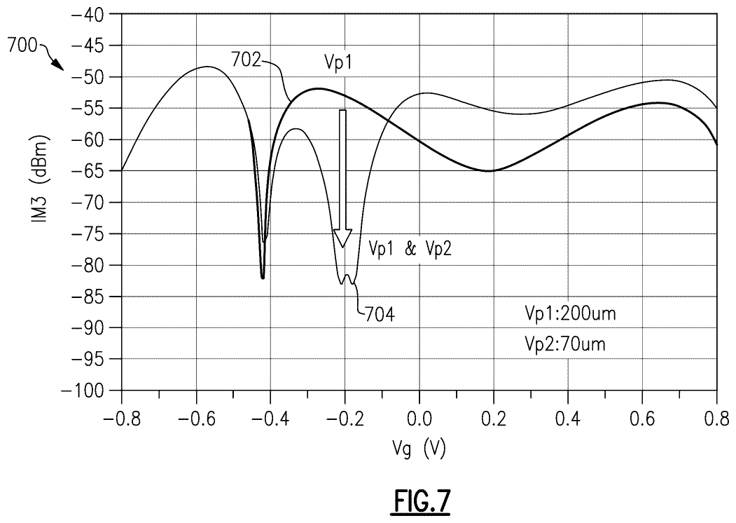

Properties of the second device 304 may be controlled to optimize additional performance parameters including, for example, a third-order intermodulation distortion (IM3). Performance parameters may include parameters indicative of how efficiently and/or effectively the power amplifier 300 is operating, such as IM3, gm3, and so forth. It may be advantageous to minimize the IM3 value. FIG. 7 illustrates a graph 700 depicting an IM3 value as a function of gate voltage according to an example. A first trace 702 indicates an IM3 value as a function of gate voltage for the first device 302 used in isolation, that is, without the second device 304 (that is, as though the second device 304 were omitted). A second trace 704 indicates an IM3 value as a function of gate voltage for the first device 302 and the second device 304 used in combination (that is, as illustrated in FIG. 3). Comparing the first trace 702 to the second trace 704 around an operating gate voltage of approximately −0.2 V, the IM3 value indicated by the second trace 704 is substantially lower than the IM3 value indicated by the first trace 702; accordingly, the IM3 value may also be optimized around the operating gate voltage value of approximately −0.2 V. As noted above, operating parameters of the second device 304 (for example, the gate width, pinch-off voltage, and so forth) may be controlled based on operating conditions (for example, a gate voltage, a drain voltage, and so forth). FIG. 7 discusses an example in which the operating gate voltage is approximately −0.2 V, and the operating parameters are selected to yield desired performance parameters (for example, an IM3 value) around the operating gate voltage. In another example, however, an operating gate voltage may be another value, such as approximately 0.05 V.

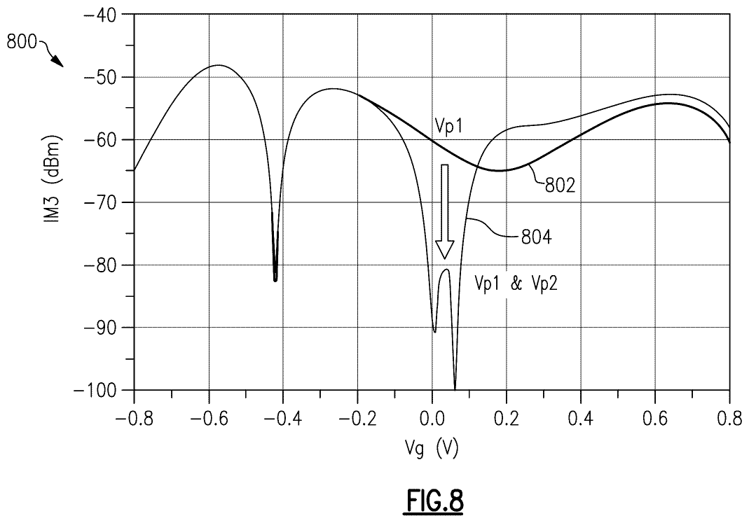

FIG. 8 illustrates a graph 800 depicting an IM3 value as a function of gate voltage according to another example. A first trace 802 indicates an IM3 value as a function of gate voltage for the first device 302 used in isolation, that is, without the second device 304 (that is, as though the second device 304 were omitted). A second trace 804 indicates an IM3 value as a function of gate voltage for the first device 302 and the second device 304 used in combination (that is, as illustrated in FIG. 3). In the example of FIG. 8, the operating conditions may include a gate voltage of approximately 0.05 V, and the operating parameters of the second device 304 may be different than those in the example of FIG. 7 to accommodate the different gate voltage.

The pinch-off voltage of the second device 304 in the example of FIG. 7 may be different than the pinch-off voltage of the second device 304 in the example of FIG. 8. Whereas the Schottky diode of the second device 304 may have a height of approximately 70 μm in the example corresponding to FIG. 7, the second device 304 may have a Schottky-diode height of approximately 16 μm in the example corresponding to FIG. 8. Varying the height of the Schottky diode (and thus varying the pinch-off voltage) may therefore be used to yield desired performance parameters at given operating conditions.

In various examples, the first device 302 may be a primary amplifying device and the second device 304 may be an auxiliary device. In other examples, however, the first device 302 may be an auxiliary device and the second device 304 may be a primary amplifying device. Furthermore, although some example power amplifiers discussed above may include a single auxiliary device, in other examples a power amplifier may include two or more auxiliary devices. Adding additional auxiliary devices may widen an operating range of the gate voltage over which performance is optimized.

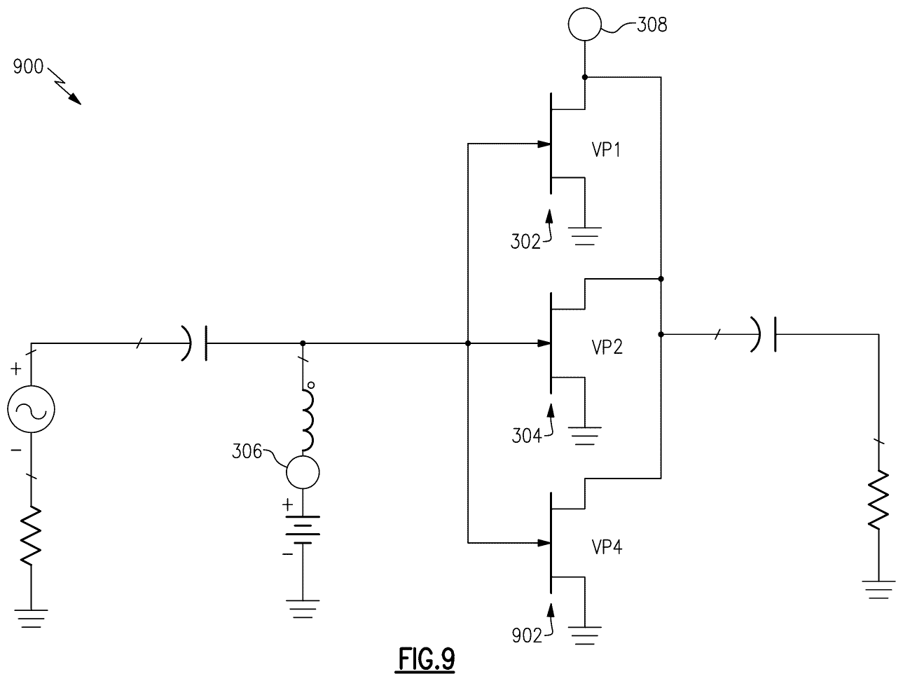

For example, FIG. 9 illustrates a schematic diagram of a power amplifier 900 according to another example. The power amplifier 900 includes the first device 302, the second device 304, the gate voltage node 306, the drain voltage node 308, and a third device 902. The third device 902 is coupled to the gate voltage node 306 at a gate connection, is coupled to the drain voltage node 308 at a drain connection, and is coupled to a reference node (for example, ground) at a source connection.

In various examples, one of the devices 302, 304, 902 (for example, the first device 302) may act as a primary amplifying device, and the remaining devices (for example, the second device 304 and third device 902) may act as auxiliary devices to yield desired performance parameters. Derivative superposition may be used to combine the performance-parameter values of any arbitrary number of devices. Accordingly, additional auxiliary devices may be added to further modify the net performance parameters to achieve desired results.

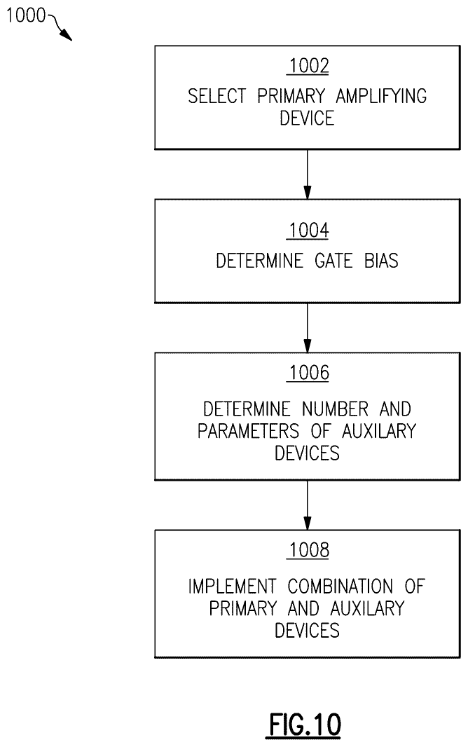

FIG. 10 illustrates a process 1000 of implementing a power amplifier according to an example.

At act 1002, a primary amplifying device is selected. For example, the primary amplifying device may include a MOSFET. In various examples, the first device 302 may be an example of a primary amplifying device. The primary amplifying device may be selected at least in part based on desired power-amplifier parameters, such as a desired gain.

At act 1004, a gate voltage bias is determined. For example, the gate voltage bias may be a gate voltage applied to the gate voltage node 306. Gate voltage may be selected based on parameters including a desired gain, power-consumption limitations, noise limitations, and so forth.

At act 1006, a number of auxiliary devices, and operating parameters thereof, are selected. The number of auxiliary devices may include one device, two devices, or more than two devices. The operating parameters may include, for example, pinch-off voltage, gate width, and so forth. As noted above, performance parameters of the primary amplifying device (for example, the first device 302), such as gm3, IM3, and so forth, may be known based on the gate voltage applied to the primary amplifying device. The number of auxiliary devices and operating parameters thereof may be selected based on various design objectives, such as minimizing the gm3 and IM3 values around the gate voltage bias point. Accordingly, in some examples a number of auxiliary devices and operating parameters thereof may be selected to have equal and opposite gm3 and/or IM3 values, for example, at a given operating gate voltage bias point. In various examples, additional factors may be considered in addition to optimizing certain performance parameters, such as by minimizing gm3 and/or IM3. For example, because increasing the number of devices in a power amplifier may increase cost, die area, and/or power consumption, the advantages of increasing the number of devices (for example, optimizing performance parameters) may be weighed against the costs of increasing the number of devices (for example, the cost, die area, and/or power consumption).

At act 1008, the primary amplifying device and auxiliary amplifying device(s) may be implemented. Implementing the devices may include coupling them in the manner depicted in the power amplifier 300, the power amplifier 900, or another topology. The power amplifier may then be used to amplify an input signal to provide an amplified output signal with desired performance parameters.

Accordingly, an arbitrary number of auxiliary devices may be coupled to a primary amplifying device in a power amplifier. Each of the auxiliary devices may be designed with a desired pinch-off voltage and/or gate width to yield desired performance parameters when operating in combination with the primary amplifying device. The pinch-off voltage may determine a general shape of a performance parameter as a function of gate voltage, and the gate width may determine an amplitude of the performance parameter. Additional auxiliary devices may be added to achieve desired performance results, such as by widening the range of gate voltages over which performance is optimized. While the number and parameters of the auxiliary devices may be selected to achieve desired performance results, all of the devices (including both the primary amplifying device and the auxiliary device [s]) may receive the same bias signals, such as the same gate voltages. This may simplify circuit design as compared to, for example, the power amplifier 200, in which different gate voltages are applied to the primary amplifying device and the auxiliary device. Although certain examples of performance parameters are provided for purposes of example, such as gm3 and IM3, additional performance parameters, such as an output third-order intercept point (OIP3) and/or input third-order intercept point (IIP3), may also be evaluated in various examples.

Various controllers, such as a controller of the power-management system 110, may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A power amplifier comprising:
an input to receive an input signal;
an output to provide an amplified output signal;
a gate voltage bias node to receive a gate voltage bias signal;
a first amplifier device having a first gate connection coupled to the gate voltage bias node and configured to receive the gate voltage bias signal; and
a second amplifier device having a second gate connection coupled to the gate voltage bias node and configured to receive the gate voltage bias signal.

2. The power amplifier of claim 1 further comprising a drain voltage bias node to receive a drain voltage bias signal, wherein the first amplifier device includes a first drain connection coupled to the drain voltage bias node and configured to receive the drain voltage bias signal and the second amplifier device includes a second drain connection coupled to the drain voltage bias node and configured to receive the drain voltage bias signal.

3. The power amplifier of claim 2 wherein the first amplifier device includes a first source connection coupled to a reference node and the second amplifier device includes a second source connection coupled to the reference node.

4. The power amplifier of claim 3 further comprising a third amplifier device having a third gate connection coupled to the gate voltage bias node and configured to receive the gate voltage bias signal, a third drain connection coupled to the drain voltage bias node and configured to receive the drain voltage bias signal, and a third source connection coupled to the reference node.

5. The power amplifier of claim 2 further comprising a third amplifier device having a third gate connection coupled to the gate voltage bias node and configured to receive the gate voltage bias signal and a third drain connection coupled to the drain voltage bias node and configured to receive the drain voltage bias signal.

6. The power amplifier of claim 1 further comprising a third amplifier device having a third gate connection coupled to the gate voltage bias node and configured to receive the gate voltage bias signal.

7. The power amplifier of claim 1 wherein the first amplifier device is a primary amplifying device and the second amplifier device is an auxiliary biasing device.

8. The power amplifier of claim 7 further comprising at least one additional auxiliary biasing device.

9. The power amplifier of claim 8 wherein at least one operating parameter of the auxiliary biasing device and the at least one additional auxiliary biasing device is selected to yield a respective desired value of at least one performance parameter under at least one operating condition.

10. The power amplifier of claim 9 wherein the at least one operating parameter includes at least one of a pinch-off voltage and a gate width.

11. The power amplifier of claim 9 wherein the at least one performance parameter includes at least one of third-order transconductance, third-order intermodulation, input third-order intercept point, or output third-order intercept point.

12. The power amplifier of claim 9 wherein the at least one operating condition includes a value of the gate voltage bias signal.

13. The power amplifier of claim 7 wherein at least one operating parameter of the auxiliary biasing device is selected to yield a respective desired value of at least one performance parameter under at least one operating condition.

14. The power amplifier of claim 13 wherein the at least one operating parameter includes at least one of a pinch-off voltage and a gate width.

15. The power amplifier of claim 13 wherein the at least one performance parameter includes at least one of third-order transconductance, third-order intermodulation, input third-order intercept point, or output third-order intercept point.

16. The power amplifier of claim 13 wherein the at least one operating condition includes a value of the gate voltage bias signal.

17. A method of operating a power amplifier including an input, an output, a gate voltage bias node, a first amplifier device, and a second amplifier device, the method comprising:
receiving an input signal at the input;
amplifying, by at least one of the first amplifier device or the second amplifier device, the input signal to produce an amplified output signal;
providing the amplified output signal to the output; and
providing a gate voltage bias signal to a first gate connection of the first amplifier device and to a second gate connection of the second amplifier device.

18. The method of claim 17 further comprising providing a drain voltage bias signal to a first drain connection of the first amplifier device and to a second drain connection of the second amplifier device.

19. The method of claim 17 further comprising selecting a value of at least one operating parameter of the second amplifier device based on the gate voltage bias signal.

20. The method of claim 19 wherein the at least one operating parameter includes at least one of a pinch-off voltage and a gate width.
